(19) United States
(12) Patent Application Publication
(10) Pub. No.: US 2024/0142181 A1
(43) Pub. Date: May 2, 2024

(54) TWO-PHASE IMMERSION-TYPE HEAT DISSIPATION STRUCTURE HAVING SKIVED FIN WITH HIGH POROSITY

(71) Applicant: AMULAIRE THERMAL TECHNOLOGY, INC., New Taipei City (TW)

(72) Inventors: CHUN-TE WU, New Taipei City (TW); CHING-MING YANG, New Taipei City (TW); YU-WEI CHIU, New Taipei City (TW); TZE-YANG YEH, New Taipei City (TW)

(21) Appl. No.: 17/975,558

(22) Filed: Oct. 27, 2022

(51) Int. Cl. F28F 3/04; C23F 1/00; F28F 21/08

(52) U.S. Cl. CPC F28F 3/048; C23F 1/00; F28F 21/084; F28F 21/085; B33Y 80/00

(57) ABSTRACT

A two-phase immersion-type heat dissipation structure having skived fin with high porosity is provided. The two-phase immersion-type heat dissipation structure having skived fin with high porosity includes a porous heat dissipation structure having a total porosity that is equal to or greater than 5%. The porous heat dissipation structure includes a porous substrate and a plurality of porous and skived fins. The porous substrate has a first surface and a second surface that face away from each other. The second surface of the porous substrate is configured to be in contact with a heating element that is immersed in a two-phase coolant. The plurality of porous and skived fins are integrally formed on the first surface of the porous substrate by skiving. A first porosity of the plurality of porous and skived fins is greater than a second porosity of the porous substrate.

### FIELD OF THE DISCLOSURE

The present disclosure relates to a heat dissipation structure, and more particularly to a two-phase immersion-type heat dissipation structure having skived fin with high porosity.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides a two-phase immersion-type heat dissipation structure having skived fin with high porosity.

In one aspect, the present disclosure provides a two-phase immersion-type heat dissipation structure having skived fin with high porosity. The two-phase immersion-type heat dissipation structure includes a porous heat dissipation structure. The porous heat dissipation structure has a total porosity that is equal to or greater than 5%, and includes a porous substrate, and a plurality of porous and skived fins. The porous substrate has a first surface and a second surface that face away from each other. The second surface of the porous substrate is configured to be in contact with a heating element that is immersed in a two-phase coolant. The plurality of porous and skived fins are integrally formed on the first surface of the porous substrate by skiving. The plurality of porous and skived fins have a first porosity, the porous substrate has a second porosity, and the first porosity is greater than the second porosity.

In certain embodiments, the porous heat dissipation structure is made of one of copper, copper alloy, aluminum, aluminum alloy, and silver.

In certain embodiments, the porous heat dissipation structure is formed by metal powder sintering, and metal powder used for sintering of the porous heat dissipation structure has a D50 that is from 10 μm to 800 μm.

In certain embodiments, the porous heat dissipation structure is formed by using a chemical solution to chemically etch a metal, and the chemical solution that is used to form the porous heat dissipation structure is one of a phosphoric microetching solution, a sulfuric microetching solution, and ferric chloride etching solution.

In certain embodiments, a number of pores of the plurality of porous and skived fins are increased via one of chemical solution deposition, electroplating, and vapor deposition.

In certain embodiments, a ratio of a thickness of each of the plurality of porous and skived fins to a distance between any two adjacent ones of the plurality of porous and skived fins is between 0.4 and 1.2.

In certain embodiments, the two-phase immersion-type heat dissipation structure having skived fin with high porosity further includes a highly thermally conductive structure being bonded to the second surface of the porous substrate, so that the second surface of the porous substrate is in indirect contact with the heating element through the highly thermally conductive structure.

In certain embodiments, the highly thermally conductive structure is a solid metal plate made of copper, copper alloy, or aluminum alloy.

In certain embodiments, the highly thermally conductive structure is made of graphite having high thermal conductivity.

In certain embodiments, an enclosed vacuum chamber is formed inside the highly thermally conductive structure and contains liquid.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a two-phase immersion-type heat dissipation structure according to a first embodiment of the present disclosure;

FIG. 2 is an enlarged view of part II of FIG. 1;

FIG. 3 is a schematic side view of a two-phase immersion-type heat dissipation structure according to a second embodiment of the present disclosure; and

FIG. 4 is a schematic side view of a two-phase immersion-type heat dissipation structure according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

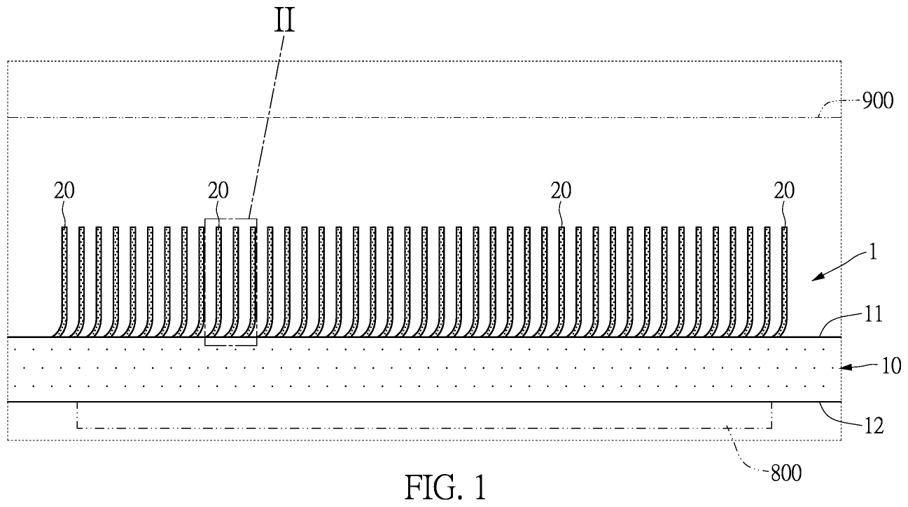

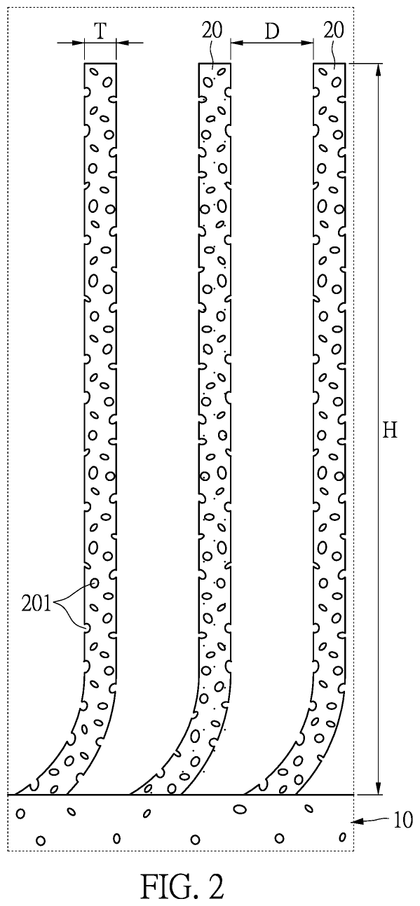

Referring to FIG. 1 and FIG. 2, a first embodiment of the present disclosure provides a two-phase immersion-type heat dissipation structure having skived fin with high porosity for being in contact with a heating element (heat source) that is immersed in a two-phase coolant. As shown in FIG. 1 and FIG. 2, the two-phase immersion-type heat dissipation structure having skived fin with high porosity provided in this embodiment of the present disclosure includes a porous heat dissipation structure 1 having a total porosity that is equal to or greater than 5% (preferably from 7% to 15%) and being immersed in a two-phase coolant 900, such that an amount of bubbles is greatly increased so as to greatly enhance a heat-dissipation effect.

The porous heat dissipation structure 1 of the present disclosure can be made of a metal such as copper, copper alloy, aluminum, aluminum alloy, or silver. Furthermore, the porous heat dissipation structure 1 of the present disclosure can be formed by metal powder sintering. Moreover, metal powder used for sintering of the porous heat dissipation structure 1 has an average particle diameter (D50) that is from 10 μm to 800 μm, so that the porous heat dissipation structure 1 can have a total porosity that is equal to or greater than 5%.

In this embodiment, the porous heat dissipation structure 1 can also be formed by chemical etching. Specifically, the porous heat dissipation structure 1 is formed by using a chemical solution to chemically etch a metal, and the chemical solution that is used to form the porous heat dissipation structure 1 is one of a phosphoric microetching solution, a sulfuric microetching solution, and ferric chloride etching solution.

In addition, the porous heat dissipation structure 1 or the present disclosure includes a porous substrate 10 and a plurality of porous and skived fins 20. The porous substrate has a first surface 11 and a second surface 12 that face away from each other, and the second surface 12 of the porous substrate 10 is configured to be in contact with a heating element 800 that is immersed in the two-phase coolant 900. The second surface 12 and the heating element 800 can be in direct contact or in indirect contact (e.g., thermal contact) through an intermediate layer. The plurality of porous and skived fins 20 are integrally formed on the first surface 11 of the porous substrate 10 by skiving. That is, the plurality of porous and skived fins 20 that are arranged in high density are integrally formed on the first surface 11 of the porous substrate 10 by skiving, so that the plurality of porous and skived fins 20 and the porous substrate 10 are integrally formed by a same material. Moreover, a number of pores 201 of a surface of the plurality of porous and skived fins can be increased via chemical solution deposition, electroplating, or vapor deposition (e.g., physical vapor deposition or chemical vapor deposition).

In this embodiment, a thickness T of each of the plurality of porous and skived fins 20 is preferably between 0.1 mm and 1.0 mm, and a ratio of the thickness T of each of the plurality of porous and skived fins 20 to a distance D between any two adjacent ones of the plurality of porous and skived fins 20 is between 0.4 and 1.2. Furthermore, a height H of each of the plurality of porous and skived fins 20 is higher than 3 mm.

In this embodiment, the plurality of porous and skived fins 20 have a first porosity, the porous substrate 10 has a second porosity, and the first porosity is greater than the second porosity, so that a mechanical strength of the porous substrate 10 having a lower porosity is higher than a mechanical strength of the plurality of porous and skived fins 20 having a higher porosity. That is, in the porous heat dissipation structure 1, a mechanical strength of a main structure is greater than a mechanical strength of a non-main structure. Therefore, in the porous heat dissipation structure 1 of the present embodiment, the plurality of porous and skived fins 20 that are arranged in very high density can be used to improve an immersion-type heat dissipation effect, and the plurality of porous and skived fins 20 having high porosity can be used to increase an amount of bubbles generated. Therefore, in this embodiment, the porous heat dissipation structure 1 can achieve upholding a high mechanical strength and improving the immersion-type heat dissipation effect.

### Second Embodiment

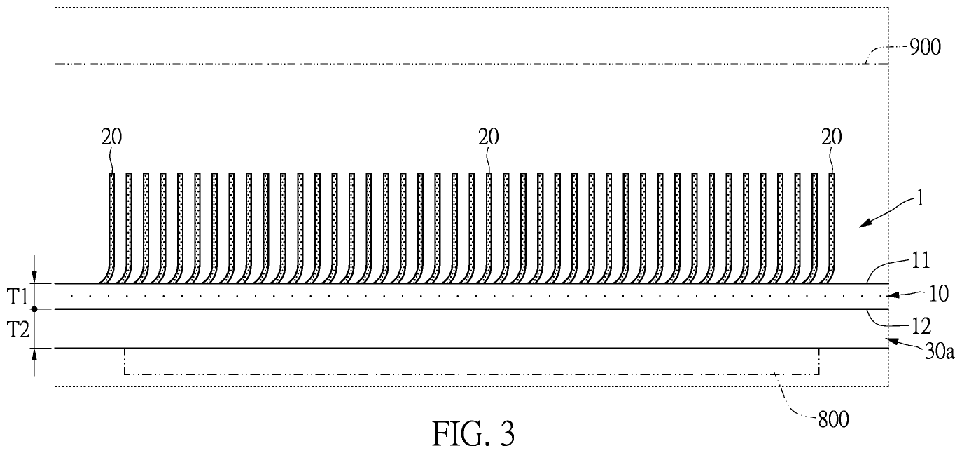

Referring to FIG. 3, a second embodiment of the present disclosure is substantially the same as the first embodiment, and the difference therebetween is described as follows.

In this embodiment, the two-phase immersion-type heat dissipation structure having skived fin with high porosity further includes a highly thermally conductive structure 30a. The highly thermally conductive structure 30a is a thermally conductive structure having a thermal conductivity greater than 380 W/mK, and the highly thermally conductive structure 30a is bonded to the second surface 12 of the porous substrate 10, so that the second surface 12 of the porous substrate 10 is in indirect contact with the heating element 800 that is immersed in the two-phase coolant 900. In detail, the highly thermally conductive structure 30a can be bonded to the second surface 12 of the porous substrate 10 by soldering, friction stir welding, gluing, diffusion, and the like.

In this embodiment, the highly thermally conductive structure 30a can be a solid metal plate that is made of copper, copper alloy or aluminum alloy. In addition, the highly thermally conductive structure 30a can also be made of graphite having high thermal conductivity. Furthermore, for improving a thermal conductivity, a thickness T2 of the highly thermally conductive structure 30a needs to be equal to or greater than 60% of a thickness (i.e., a thickness T1 of the porous substrate 10 plus the thickness T2 of the highly thermally conductive structure 30a) of the embodiment substrate in total.

### Third Embodiment

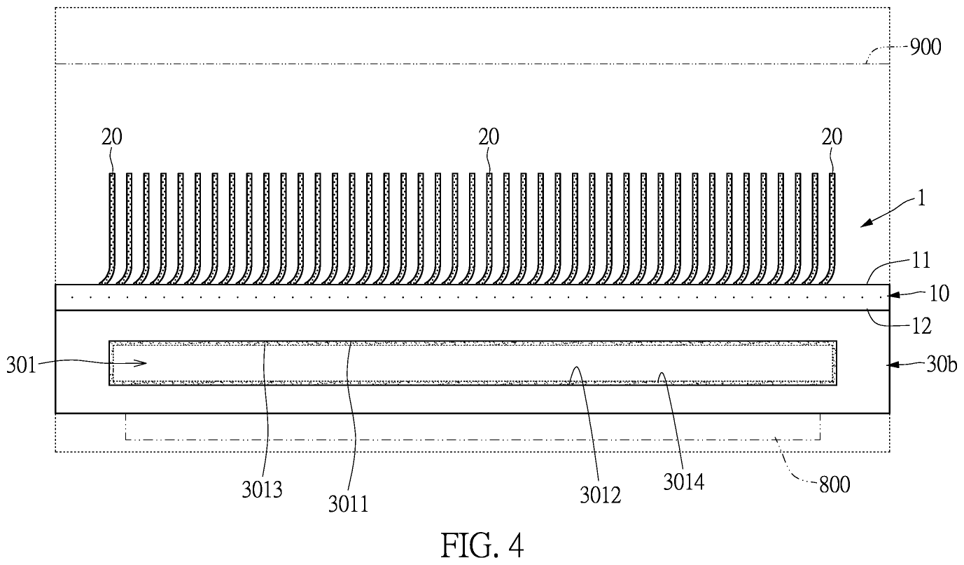

Referring to FIG. 4, a third embodiment of the present disclosure is substantially the same as the first embodiment and the second embodiment, and the difference therebetween is described as follows.

In this embodiment, an enclosed vacuum chamber 301 is formed inside a highly thermally conductive structure 30b, and the enclosed vacuum chamber 301 has a chamber top wall 3011 and a chamber bottom wall 3012 that respectively have an upper sintered body 3013 and a lower sintered body 3014 formed thereon. The enclosed vacuum chamber 301 contains an adequate amount of liquid that can be water or acetone, and a bottom surface of the highly thermally conductive structure 30b can be in contact with the heating element 800 that is immersed in the two-phase coolant 900. Accordingly, for the heating element 800 immersed in the two-phase coolant 900, heat generated thereby can be removed through an endothermic gasification process of the two-phase coolant 900. In addition, the highly thermally conductive structure 30b can be in contact with the heating element 800 and absorb the heat generated thereby, so that the liquid contained in the enclosed vacuum chamber 301 is gasified or vaporized into vapor and then distributed to the porous substrate 10. The heat is rapidly conducted to the plurality of porous and skived fins 20 that are integrally formed on the porous substrate 10 and arranged in very high density. The heat absorbed by the plurality of porous and skived fins 20 is then removed through the endothermic gasification process of the two-phase coolant 900, and the vapor in the enclosed vacuum chamber 301 flows back to the chamber bottom wall 3012 after transferring out the heat and being condensed at the chamber top wall 3011. By performing the loop in a high speed, heat generated by the heating element 800 can be rapidly delivered outward, thereby improving an overall immersion-type heat dissipation effect.

### Beneficial Effects of the Embodiments

In conclusion, in the two-phase immersion-type heat dissipation structure having skived fin with high porosity, by technical features of “a porous heat dissipation structure having a total porosity that is equal to or greater than 5%,” “the porous heat dissipation structure having a porous substrate and a plurality of porous and skived fins,” “the porous substrate having a first surface and a second surface that face away from each other, the second surface of the porous substrate being configured to be in contact with a heating element that is immersed in a two-phase coolant, and the plurality of porous and skived fins being integrally formed on the first surface of the porous substrate by skiving,” and “the plurality of porous and skived fins having a first porosity, the porous substrate having a second porosity, and the first porosity being greater than the second porosity,” an overall immersion-type heat dissipation effect can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion-type heat dissipation structure having skived fin with high porosity, comprising:
a porous heat dissipation structure having a total porosity that is equal to or greater than 5%, wherein the porous heat dissipation structure includes:
a porous substrate having a first surface and a second surface that face away from each other, wherein the second surface of the porous substrate is configured to be in contact with a heating element that is immersed in a two-phase coolant; and
a plurality of porous and skived fins being integrally formed on the first surface of the porous substrate by skiving;
wherein the plurality of porous and skived fins have a first porosity, the porous substrate has a second porosity, and the first porosity is greater than the second porosity.

2. The two-phase immersion-type heat dissipation structure according to claim 1, wherein the porous heat dissipation structure is made of one of copper, copper alloy, aluminum, aluminum alloy, and silver.

3. The two-phase immersion-type heat dissipation structure according to claim 1, wherein the porous heat dissipation structure is formed by metal powder sintering, and metal powder used for sintering of the porous heat dissipation structure has a D50 that is from 10 μm to 800 μm.

4. The two-phase immersion-type heat dissipation structure according to claim 1, wherein the porous heat dissipation structure is formed by using a chemical solution to chemically etch a metal, and the chemical solution that is used to form the porous heat dissipation structure is one of a phosphoric microetching solution, a sulfuric microetching solution, and ferric chloride etching solution.

5. The two-phase immersion-type heat dissipation structure according to claim 3, wherein a number of pores of the plurality of porous and skived fins are increased via one of chemical solution deposition, electroplating, and vapor deposition.

6. The two-phase immersion-type heat dissipation structure according to claim 4, wherein a number of pores of the plurality of porous and skived fins are increased via one of chemical solution deposition, electroplating, and vapor deposition.

7. The two-phase immersion-type heat dissipation structure according to claim 1, wherein a ratio of a thickness of each of the plurality of porous and skived fins to a distance between any two adjacent ones of the plurality of porous and skived fins is between 0.4 and 1.2.

8. The two-phase immersion-type heat dissipation structure according to claim 1, further comprising a highly thermally conductive structure being bonded to the second surface of the porous substrate, so that the second surface of the porous substrate is in indirect contact with the heating element through the highly thermally conductive structure.

9. The two-phase immersion-type heat dissipation structure according to claim 8, wherein the highly thermally conductive structure is a solid metal plate made of copper, copper alloy, or aluminum alloy.

10. The two-phase immersion-type heat dissipation structure according to claim 8, wherein the highly thermally conductive structure is made of graphite having high thermal conductivity.

11. The two-phase immersion-type heat dissipation structure according to claim 8, wherein an enclosed vacuum chamber is formed inside the highly thermally conductive structure and contains liquid.
